(19) United States
(12) Patent Application Publication
(10) Pub. No.: US 2005/0111188 A1
(43) Pub. Date: May 26, 2005

(54) Thermal management device for an integrated circuit

(76) Inventors: Anandaroop Bhattacharya, Phoenix, AZ (US); Ravi S. Prasher, Tempe, AZ (US); Jerome L. Garcia, Chandler, AZ (US); Suzana Prstic, Chandler, AZ (US)

Correspondence Address: SCHWABE, WILLIAMSON & WYATT, P.C.;PACWEST CENTER, SUITES 1600-1900, 1211 SW FIFTH AVENUE, PORTLAND, OR, 97204, US

(21) Appl. No.: 10/723,533

(22) Filed: Nov. 26, 2003

(51) Int. Cl. H05K 7/20

(52) U.S. Cl. 361/699; 361/708; 165/80.2; 165/80.5

(57) ABSTRACT

Embodiments of the present invention include an apparatus, method, and system for an electronic assembly with a thermal management device including a porous medium.

### FIELD OF THE INVENTION

Disclosed embodiments of the present invention relate to the field of integrated circuits, and more particularly to an electronic assembly with a thermal management device including a porous medium.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 is a cross-sectional view of an electronic assembly including a thermal management device with a porous medium, in accordance with an embodiment of the present invention;

FIGS. 2(a) and 2(b) are cross-sectional views of an electronic assembly including a thermal management device with a porous medium coupled to a heat source, in accordance with an embodiment of the present invention;

FIG. 3(a) is a cross-sectional view of an electronic assembly including a thermal management device with a porous medium with an accompanying illustration of an evaporation/condensation cycle, in accordance with an embodiment of the present invention;

FIG. 3(b) is a heat graph corresponding to the temperature across the surface of the heat source of FIG. 3(a), in accordance with an embodiment of the present invention; and

FIG. 4 depicts a system including an electronic assembly in accordance with an embodiment of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the embodiments of the present invention. It should also be noted that directions such as up, down, back, and front may be used in the discussion of the drawings. These directions are used to facilitate the discussion of the drawings and are not intended to restrict the application of the embodiments of this invention. Therefore, the following detailed description is not to be taken in a limiting sense and the scope of the embodiments of the present invention are defined by the appended claims and their equivalents.

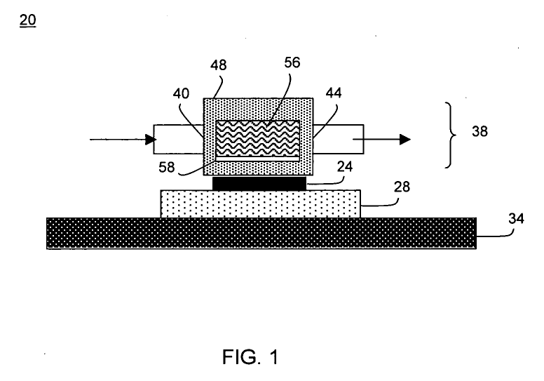

FIG. 1 illustrates a cross-sectional view of an electronic assembly 20 including a thermal management device 38 in accordance with an embodiment of this invention. In this embodiment the thermal management device 38, including a porous medium 56, may be coupled to a heat source 24 to at least facilitate management of heat generated by the heat source 24. This facilitation of heat management of this embodiment may include thermally coupling the heat source 24 to a remote heat exchanger.

The heat source 24 could include an integrated circuit, which may be formed in a rectangular piece of semiconductor material called a chip or a die. Examples of the semiconductor material include, but are not limited to silicon, silicon on sapphire, or gallium arsenide. The heat source 24 could contain one or more die attached to a substrate 28 for support, to interconnect multiple components, and/or to facilitate electrical connections with other components. The heat source 24 may be attached to the substrate 28 by solder ball connections known as controlled collapse chip connectors (C4), or by some other means. The heat source 24 combined with the substrate 28 may be referred to as a first-level package.

The first-level package may be connected to a board 34 in order to interconnect multiple components such as other die, high-power resistors, mechanical switches, capacitors, etc., which may not be readily placed onto the substrate 28. Examples of the board 34 could include, but are not limited to a carrier, a printed circuit board (PCB), a printed circuit card (PCC), and a motherboard. Board materials could include, but are not limited to ceramic (thick-filmed, cofired, or thin-filmed), plastic, and glass. The first-level packages can be mounted directly onto the board 34 by solder balls, by a pin/socket connection, or by some other means.

In one embodiment, the porous medium 56 may be substantially disposed within a case 48. The case 48 may have an inlet 40 and an outlet 44. In one embodiment the inlet 40 may be coupled to a pump and the outlet 44 coupled to a heat exchanger by pipes that are adapted to transport cooling fluids between the components. The pump, which may include an external motor and a pumping mechanism internal to the pipe, may create a pressure change to at least assist the flow of the cooling fluid from the inlet 40 to the outlet 44 through the porous medium 56. This may result in interstitial movement of the cooling fluid over an extended surface area. The extended surface area may result in more contact, and therefore potentially more convection heat transfer between the porous medium 56 and the cooling fluid. The total contact surface area may be related to the porosity of the porous medium. In one embodiment of the present invention the porosity of the porous medium may be between 80%-95% by volume fraction of air.

The porous medium 56 may also serve to enhance the heat transfer coefficient due to local thermal dispersion caused by recirculating eddies that are shed in the wake of fluid flow past fibers of the porous medium 56. This, in turn may help to reduce the thermal resistance from the heat source 24 to the heat exchanger, which could increase the total amount of heat transferred per volume of cooling fluid passed through the porous medium 56. The cooling fluid may exit the case 48 through the outlet 44 and transfer a portion of the thermal energy from the heat source 24 to the remote heat exchanger. The heat exchanger may be any known or to be designed heat dissipation mechanism. In one embodiment the heat exchanger may dissipate excess thermal energy from the cooling fluid and present the fluid to the pump so that it may be reintroduced to the thermal management device 38. Examples of the cooling fluid may include, but are not limited to a gas (e.g., air) and a liquid (e.g., water, alcohol, perfluorinated liquids, etc.).

In one embodiment, the porous medium 56 may be a microporous metal foam that includes numerous interlaced and seemingly randomly placed pore channels. In one embodiment the pore diameters of the microporous foam may be between 50 μm-1 mm. The heat transfer, or the amount of thermal energy that can be removed from the heat source 24 per volume of cooling fluid, may be roughly inversely proportional to the pore diameter of the porous medium 56. Additionally, the pressure drop of the cooling liquid may be roughly inversely proportional to the pore diameter. Therefore, it follows that a high heat transfer may require small pore sizes, which in turn may result in large pressure drops. Pressure drops of these magnitudes may be handled by any suitably efficient pumps that are known or to be designed. The microporous metal foam may include, for example, aluminum, carbon, or nickel.

The parameters of the porous medium 56 may be customized for application in a particular embodiment. For example, in one embodiment, the pore size may be adjusted in portions of the porous medium 56 to increase fluid flow through those areas. Additional embodiments may include the porous medium 56 being compressed in a particular direction to give elongated pores that have the potential of lowering the pressure drop for a given area, possibly without an appreciable increase in thermal resistance.

In one embodiment the porous medium 56 may be disposed within, and substantially filling the case 48. The porous medium 56 may be coupled to the internal portion of the case by a thermal interface material 58 to at least facilitate the heat transfer of the thermal management device 38 by providing a thermally conductive path between the case 48 and the porous medium 56.

A wide variety of suitable thermal interface materials may be used in various embodiments in accordance with this invention. Some attributes that may be considered with respect to a particular embodiment may be a low thermal resistance, secure mechanical adhesion, and ease of application. Additionally, particular design considerations of a given embodiment could be factored in to decide what type of thermal interface material to use. For example, in one embodiment a thermal interface material with a low thermal resistance but poor mechanical adhesion could be supplemented by providing for additional mechanical connectors such as screws, clips, or spring-loaded pins. Examples of types of thermal interface materials include, but are not limited to, a thin layer of solder paste, phase-change materials, thermal adhesives (e.g., a highly filled epoxy or acrylic), double-sided thermal tape, and thermal interface pads.

The process for attaching the porous medium 56 and the case 48 may vary depending on the type of materials involved in a particular embodiment. In an embodiment that uses a solder paste as the thermal interface material 58, the thermal management device 38 may be placed in a reflow oven in order to reflow the solder.

In another embodiment, it may be possible to “grow” the porous medium 56 directly on the case 48. In this embodiment a granular structuring layer (e.g., salt) may be placed in the area where the porous medium is desired. The grain size of the structuring layer may be roughly the desired pore size of the porous medium 56. The salt used in this example may have a diameter of approximately 0.5 mm. A fine metal powder, e.g., aluminum, may be added over the salt. Because of the relative size difference, the powder may fill in the gaps between the salt grains. The mixture could then be heated to the melting temperature of the powder (which may be less than structuring layer). Once the metal flows and the mixture cools, the salt may be removed by running water which may leave an aluminum metal foam with a pore size of approximately 0.5 mm attached directly to the case 48.

The case 48 may be made of a conductive material to reduce the thermal resistance in the path between the heat source 24 and the porous medium 56. In one embodiment, only the bottom portion of the case 48, that is the side that is in closest relation to the heat source, may be made of a conductive material. The case 48 may be constructed of several pieces with the final assembly occurring after the porous medium 56 is positioned on the inside. In one embodiment, the case includes at least a top and bottom copper plate which corresponds roughly to the size of the heat source 24. The case 48 could be made of any type of conductive material including, but not limited to, copper (Cu), aluminum (Al), and aluminum silicon carbide (AlSiC). Design considerations for choosing the case material for a given embodiment may include conductivity, cost, manufacturability, coefficient of thermal expansion, etc.

In one embodiment, the case 48 may be attached to the heat source 24 with a thermal interface material similar to the one used to attach the porous medium to the interior portion of the case 48. In an embodiment using a solder paste as a thermal interface material, the solder may have a lower reflow temperature than that of the C4 connections that attach the heat source 24 to the substrate 28 to prevent any unintentional reflowing.

In one embodiment a heat spreader (not shown) may be placed over the heat source 24 and attached to the substrate 28. The heat spreader may be used as an intermediary step to disperse at least a portion of the heat generated by the heat source 24 over its surface area. The heat spreader may be attached to the substrate 28 by a sealant material and thermally coupled to the heat source 24 with a thermal interface material. In this embodiment, the thermal management device may be placed on the heat spreader with a thermal interface material, similar to above embodiment.

In one embodiment the thermal management device 38 may use two-phase cooling. Two-phase cooling may occur when heat from the heat source 24 transforms a cooling liquid into a vapor. As the vapor flows away from the heat source 24 towards the heat exchanger it may cool and condense back into liquid, which may result in a release of its latent heat of vaporization. The fibers and overall density of the porous medium 56 may prevent the formation of large air bubbles that may inhibit heat transfer and restrict the quality of the vapor-fluid mixture at the outlet of the thermal management device 38. Additionally, the fibers on the porous medium 56 near the heat source 24 may assist the onset of boiling by acting as nucleation sites. Whether or not the cooling fluid will evaporate and lead to two-phase cooling may depend on the amount of heat generated by the heat source 24, as well as the flow rate of the cooling fluid. For example, in one embodiment high heat production and low flow rates may be more likely to result in two-phase flows.

As the cooling liquid vaporizes over the hot spots of the heat source there may be a corresponding increase in the pressure drop in the area. With the interconnected nature of the pore channels of embodiments of this invention there may be an equilibration of pressure from high to low pressure areas. This could result in cooling liquid flowing to the areas associated with concentrated thermal energy, thereby potentially increasing the overall heat transfer of the system.

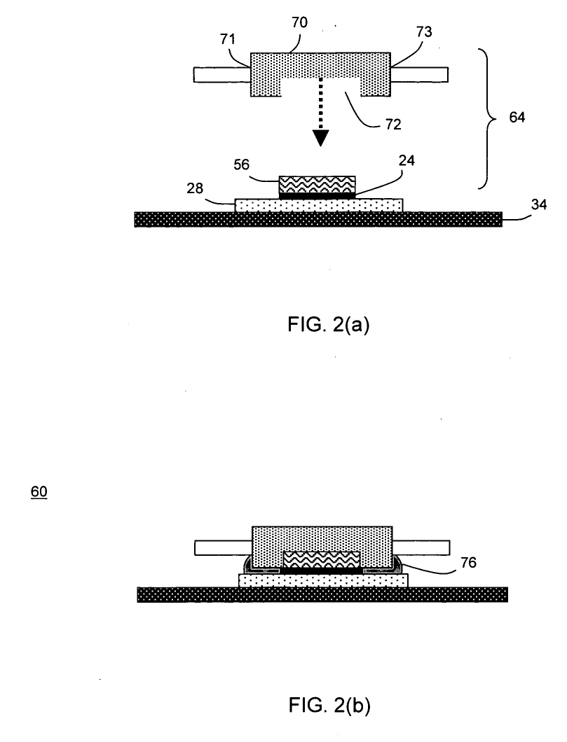

FIG. 2 depicts an exploded (a) and combined (b) cross-sectional view of an electronic assembly 60 with a thermal management device 64 in accordance with one embodiment of the present invention. In this embodiment the porous medium 56 may be coupled to the heat source 24. The porous medium 56 may be coupled to the heat source 24 by a similar process as it was attached to the case 48 discussed with reference to the embodiment depicted in FIG. 1. In the present embodiment, the case 70 may be adapted to fit over the porous medium 56 by having a cavity 72. The porous medium 56 may be attached to the interior portion of the cavity 72 by a thermal interface material, or by some other means.

In one embodiment the cavity 72 may be the same size or even slightly smaller than the porous medium 56 and the case 70 may be heated such that the cavity 72 expands large enough to be positioned over the porous medium 56. As the case 70 cools down it may shrink to form a tight fit. The case 70 may have an inlet 71 and outlet 73 for the cooling fluid flow. The inlet 71 and outlet 73 may be attached to a pump and heat exchanger, respectively, similar to the embodiment described in FIG. 1. In one embodiment a watertight seal may be formed between the heat source 24 and the case 70, which may prevent cooling fluid from leaking from the thermal management device 64. In an embodiment an epoxy sealant 76 may be used to seal any gap between the case 70 and the die. As shown in the illustrated embodiment, the epoxy sealant 76 may also serve to provide a seal between the case 70 and the substrate 28, which may reinforce the watertight seal. The epoxy sealant 76 may also at least facilitate the support of the thermal management device 64, which could reduce the amount of torsion transferred to the connections between the porous medium 56, the heat source 24 and the substrate 28.

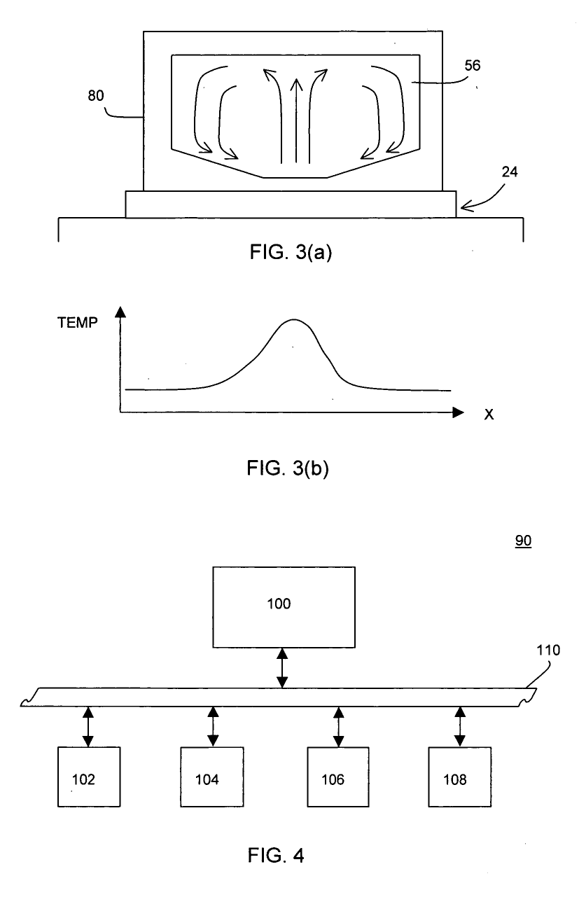

FIG. 3(a) shows a cross-sectional view of an electronic assembly including a thermal management device with a porous medium 56 illustrating an evaporation/condensation cycle, in accordance with an embodiment of the present invention. In this embodiment, there may be a relative hot spot located near the middle of the heat source 24, as shown by the corresponding temperature graph in FIG. 3(b). Die containing integrated circuits may display these non-uniform heat intensity distributions due to concentrated current flow for one reason or another. In one embodiment it may be possible to customize the case 80 and porous medium 56 to account for these concentrated heat distributions and thereby at least facilitate the thermal exchange between the heat source 24 and the heat exchanger.

The embodiment depicted by FIG. 3(a), unlike the embodiments depicted by FIG. 1 and FIG. 2, may have a closed case that does not use an inlet and an outlet. In this embodiment the cooling fluid may evaporate over the hot spot of the heat source 24 and the fluid buoyancy of the vapor may create an upward fluid motion towards the top of the case 80, which may be considered the heat exchanger of this embodiment. In this embodiment the latent heat of vaporization may be transferred to the top of the case 80 where it may be dissipated to the ambient through natural convection, or by some other means. Various embodiments may employ different types of cold plates or heat sinks attached to the top of the case 80 to assist this convection. In this embodiment as the vapor condenses back to a liquid, it may be forced to the sides of the porous medium 56. The heavier condensed fluid may trickle down the sides of the porous medium and collect back over the hot spot of the heat source 24. In an alternative embodiment, the fluid may not go through a phase change, as sufficient buoyancy induced flow may result from heated fluid without the phase change. The interior of the case 80 may be designed to facilitate these cyclical two-phase flows. In one embodiment the flow paths of the vapor and condensed liquid may travel through areas of variable pore size depending on the desired fluid dynamics of the particular embodiment.

Referring to FIG. 4, there is illustrated one of many possible systems in which embodiments of the present invention may be used. The electronic assembly 100 may be similar to the electronic assemblies depicted in above FIGS. 1, 2, and 3. In one embodiment, the electronic assembly 100 may include a microprocessor. In an alternate embodiment, the electronic assembly 100 may include an application specific IC (ASIC). Integrated circuits found in chipsets (e.g., graphics, sound, and control chipsets) may also be packaged in accordance with embodiments of this invention.

For the embodiment depicted by FIG. 4, the system 90 may also include a main memory 102, a graphics processor 104, a mass storage device 106, and an input/output module 108 coupled to each other by way of a bus 110, as shown. Examples of the memory 102 include but are not limited to static random access memory (SRAM) and dynamic random access memory (DRAM). Examples of the mass storage device 106 include but are not limited to a hard disk drive, a compact disk drive (CD), a digital versatile disk drive (DVD), and so forth. Examples of the input/output modules 108 include but are not limited to a keyboard, cursor control devices, a display, a network interface, and so forth. Examples of the bus 110 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, an entertainment unit, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

1. An apparatus comprising:
a heat source with at least one integrated circuit;
a heat exchanger; and
a thermal management device having a case including a porous medium and a fluid, to thermally couple the heat source to the heat exchanger.

2. The apparatus of claim 1, wherein the fluid is a selected one of air, water, and perfluorinated liquid.

3. The apparatus of claim 1, wherein the case comprises at least a selected one of copper and aluminum.

4. The apparatus of claim 1, wherein the porous medium includes a microporous metal foam.

5. The apparatus of claim 4, wherein the microporous metal foam includes at least a selected one of copper, aluminum, and carbon.

6. The apparatus of claim 4, wherein the microporous metal foam includes a plurality of pore channels with a pore diameter that is substantially at or between 50 μm-1 mm.

7. The apparatus of claim 6, wherein the microporous metal foam includes a plurality of areas with different pore diameters.

8. The apparatus of claim 4, wherein the microporous metal foam includes a porosity that is substantially at or above 80%.

9. The apparatus of claim 1, wherein the case includes:
an inlet coupled to a pump;
an outlet coupled to the heat exchanger; and
the pump to at least assist to produce a fluid motion through the porous medium toward the heat exchanger.

10. The apparatus of claim 9, wherein the heat source further comprises
a die including the at least one integrated circuit; and
a substrate coupled to the die to form a package.

11. The apparatus of claim 10, wherein the case substantially encloses the porous medium.

12. The apparatus of claim 11, wherein the porous medium is coupled to at least one interior wall of the case with a thermal interface material.

13. The apparatus of claim 11, wherein the case is coupled to the die with a thermal interface material.

14. The apparatus of claim 11, further comprising
a heat spreader coupled to the substrate over the die, and the case is coupled to the heat spreader with a thermal interface material.

15. The apparatus of claim 10, wherein the porous medium is coupled to the die, and the case is adapted to receive the porous medium in a cavity.

16. The apparatus of claim 15, further comprising
a substantially watertight seal between the case and the die.

17. The apparatus of claim 16, wherein the substantially watertight seal includes an epoxy sealant.

18. The apparatus of claim 15, wherein the porous medium is coupled to the die with a thermal interface material.

19. The apparatus of claim 15, wherein the die has a length, a width, and a height, and the porous medium has at least substantially the same length and width.

20. A method comprising:
operating an integrated circuit, leading to heat being sourced from the integrated circuit; and
flowing a fluid through a porous medium housed in a case to transfer thermal energy away from the integrated circuit heat source.

21. The method of claim 20, wherein flowing of a fluid comprises flowing a selected one of air, water, and perfluorinated liquid.

22. The method of claim 20, wherein the porous medium includes a microporous metal foam.

23. The method of claim 22, wherein the microporous metal foam includes a plurality of pore channels with a pore diameter that is substantially at or between 50 μm-1 mm.

24. The method of claim 20, wherein said flowing of a fluid comprises operating a pump coupled to an inlet in the case to move the fluid through the case, and the method further comprises operating a heat exchanger coupled to an outlet in the case to transfer thermal energy.

25. The method of claim 20, wherein said flowing of a fluid is induced at least in part by natural buoyancy resulting from heated portions of the fluid.

26. A system comprising:
an electronic assembly including:
a heat source with at least one integrated circuit;
a heat exchanger; and
a thermal management device having a case including a porous medium and a fluid, to thermally couple the heat source to the heat exchanger;
a dynamic random access memory coupled to the at least one integrated circuit; and
an input/output interface coupled to the at least one integrated circuit.

27. The system of claim 26, wherein the porous medium includes a microporous metal foam.

28. The system of claim 27, wherein the microporous metal foam includes a plurality of pore channels with a pore diameter that is substantially at or between 50 μm-1 mm.

29. The system of claim 26, wherein the integrated circuit is a microprocessor.

30. The system of claim 29, wherein the system is a selected one of a set-top box, an entertainment unit, and a digital versatile disk player.

31. The system of claim 26, wherein the input/output interface comprises a networking interface.
